(19) United States
(12) Patent Application Publication
(10) Pub. No.: US 2026/0020264 A1
(43) Pub. Date: Jan. 15, 2026

(54) DOUBLE-SIDED DEEP-TRENCH-CAPACITORS

(71) Applicant: Applied Materials, Inc., Santa Clara, CA (US)

(72) Inventor: Seann William Ayers, Phoenix, AZ (US)

(73) Assignee: Applied Materials, Inc., Santa Clara, CA (US)

(21) Appl. No.: 18/766,936

(22) Filed: Jul. 9, 2024

(51) Int. Cl. H01L 29/94; H01L 23/64; H01L 29/66

(52) U.S. Cl. CPC H10D 1/665; H01L 23/642; H01L 23/645; H01L 23/647; H10D 1/047

(57) ABSTRACT

Exemplary semiconductor structures may include a substrate defining a device layer. The structures may include a first deep-trench-capacitor (DTC) coupled to a first surface of the substrate. The structures may include a second DTC coupled to a second surface of the substrate opposite the first surface of the substrate.

### TECHNICAL FIELD

The present technology relates to semiconductor processes and semiconductor structures. More specifically, the present technology relates to semiconductor structures including double-sided deep-trench-capacitors.

### BACKGROUND

Deep-trench-capacitors (DTCs) are often used to add capacitance to several types of integrated circuit devices and structures. A typical DTC may include a deep trench (DT) (or high aspect ratio feature) in a semiconductor substrate (e.g., the semiconductor substrate of either a bulk silicon wafer or silicon-on-insulator (SOI) wafer). A doped region within the substrate adjacent to the trench forms one capacitor plate (i.e., a buried capacitor plate). A dielectric layer lining the trench forms the capacitor dielectric. Finally, a conductive fill material (e.g., a doped polysilicon) within the trench forms another capacitor plate. A standard contact can be formed to contact capacitor plate within the trench.

The materials and dimensions of the DTCs may impact electrical properties of the final DTC. For example, dimensions of the deep trench (or high aspect ratio feature) may be directly related to density as well as inductance and resistance. As devices continue to evolve, demands for increased capacitance density, decreased equivalent series inductance (ESL), and/or equivalent series resistance (ESR) similarly follow. However, a tradeoff between capacitance density and ESL/ESR exists.

Thus, there is a need for improved systems and methods that can be used to produce high quality devices and structures. These and other needs are addressed by the present technology.

### SUMMARY

Exemplary semiconductor structures may include a substrate defining a device layer. The structures may include a first deep-trench-capacitor (DTC) coupled to a first surface of the substrate. The structures may include a second DTC coupled to a second surface of the substrate opposite the first surface of the substrate.

In some embodiments, the first DTC may include a first plurality of high aspect ratio features. The second DTC may include a second plurality of high aspect ratio features. An aspect ratio of first plurality of high aspect ratio features may be approximately the same as an aspect ratio of the second plurality of high aspect ratio features. The first plurality of high aspect ratio features, the second plurality of high aspect ratio features, or both are characterized by a depth of less than or about 4 micron (μm). The first plurality of high aspect ratio features, the second plurality of high aspect ratio features, or both are characterized by a depth of less than or about 3 micron (μm). The first plurality of high aspect ratio features, the second plurality of high aspect ratio features, or both may be characterized by a width of less than or about 500 nanometer (nm). The first plurality of high aspect ratio features, the second plurality of high aspect ratio features, or both may be characterized by an aspect ratio of less than or about 20:1. The semiconductor structure may be characterized by a capacitance density at about 1 gigahertz (GHz) of greater than or about 4×10⁻¹² farad (F). The semiconductor structure may be characterized by an equivalent series inductance (ESL) at about 1 gigahertz (GHz) of less than or about 7×10⁻⁹ henry (H). The semiconductor structure may be characterized by an equivalent series resistance (ESR) at about 1 gigahertz (GHz) of less than or about 5 ohm (Ω).

Some embodiments of the present technology may encompass semiconductor processing methods. The methods may include processing a substrate to form a device layer. The methods may include joining the substrate to a first deep-trench-capacitor (DTC). The first DTC may be coupled to a first surface of the substrate. The methods may include joining the substrate to a second DTC. The second DTC may be coupled to a second surface of the substrate to form a semiconductor structure.

In some embodiments, the first DTC may include a first plurality of high aspect ratio features. The second DTC may include a second plurality of high aspect ratio features. The first plurality of high aspect ratio features, the second plurality of high aspect ratio features, or both may be characterized by an aspect ratio of less than or about 20:1. The first plurality of high aspect ratio features, the second plurality of high aspect ratio features, or both may be characterized by a depth of less than or about 4 micron (μm). The semiconductor structure may be characterized by a capacitance density at about 1 gigahertz (GHz) of greater than or about 4×10⁻¹² farad (F). The semiconductor structure may be characterized by an equivalent series inductance (ESL) at about 1 gigahertz (GHz) of less than or about 7×10⁻⁹ henry (H), or the semiconductor structure is characterized by an equivalent series resistance (ESR) at about 1 gigahertz (GHz) of less than or about 5 ohm (Ω).

Some embodiments of the present technology may encompass semiconductor structures. The structures may include a substrate defining a device layer. The structures may include a first deep-trench-capacitor (DTC) including a first plurality of high aspect ratio features coupled to a first surface of the substrate. The structures may include a second DTC coupled comprising a second plurality of high aspect ratio features to a second surface of the substrate. The semiconductor structure may be characterized by a capacitance density at about 1 gigahertz (GHz) of greater than or about 4×10⁻¹² farad (F). The semiconductor structure may be an equivalent series inductance (ESL) at about 1 gigahertz (GHz) of less than or about 7×10⁻⁹ henry (H), an equivalent series resistance (ESR) at about 1 gigahertz (GHz) of less than or about 5 ohm (Ω), or both.

In some embodiments, the first plurality of high aspect ratio features, the second plurality of high aspect ratio features, or both may be characterized by an aspect ratio of less than or about 20:1. The first plurality of high aspect ratio features, the second plurality of high aspect ratio features, or both may be characterized by a depth of less than or about 4 micron (μm). The semiconductor structure may be characterized by an equivalent series inductance (ESL) at about 1 gigahertz (GHz) of less than or about 7×10⁻⁹ henry (H) and an equivalent series resistance (ESR) at about 1 gigahertz (GHz) of less than or about 5 ohm (Ω).

Such technology may provide numerous benefits over conventional systems and techniques. For example, the processes and structures may permit incorporation of additional DTCs to a structure. The addition of multiple DTCs may increase the capacitance density. Additionally, the increased capacitance density may allow for reduction in equivalent series inductance (ESL) and/or equivalent series resistance (ESR). These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2 shows a side view of one embodiment of an exemplary processing system according to some embodiments of the present technology.

FIG. 3 shows exemplary operations in a method according to some embodiments of the present technology.

FIG. 4 show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As semiconductor structures and devices continue to evolve, the demand for capacitance density increase, sometimes dramatically. Increased capacitance density is critical for meeting stringent power integrity requirements of current and future semiconductor structures and devices. Conventional technologies may use a deep-trench-capacitor (DTC) to provide optimal capacitance density with minimal unwanted inductance and/or resistance parasitic.

Conventional technologies are limited to using a DTC on a single side of a device layer. In attempts to maximize capacitance density, these conventional technologies may increase a depth or length of the trench (or high aspect ratio feature) in the DTC. However, with increased depths or lengths, and increase aspect ratios of the trench or feature, inductance and/or resistance parasitic may also increase. In these conventional technologies, for example, doubling capacitance density by doubling the trench (or high aspect ratio feature) depth or length also results in a doubling of the unwanted inductance and/or resistance parasitic. More generally, any increase in capacitance density may also negatively scale the equivalent series inductance (ESL), and/or equivalent series resistance (ESR). As such, conventional technologies must carefully balance capacitance density with unwanted inductance and/or resistance parasitic.

The present technology overcomes these issues by using multiple DTCs for a single device layer. By moving the device layer to a middle portion of the chip stack, as is becoming common in modern chip stack architecture, a first DTC may be included on one side of the device layer with a second DTC being included on another side, such as an opposite side, of the device layer. By introducing a second DTC for a single device layer, a combined depth or length of the trench (or high aspect ratio feature) may be increased, thereby increasing capacitance density. Additionally, by providing a second DTC, an aspect ratio of the trenches (or high aspect ratio features) in each DTC may be reduced (or maintained compared to conventional technologies). The reduced (or maintained) aspect ratios may avoid the expected increase in ESL and ESR associated with increased capacitance density. Addtiionally, using two DTCs on opposite sides of the device layer may advantageously use the Z axis of the structure as the premium X, Y area is not compromised. Further, by using multiple DTCs, the aspect ratio of the trenches (or high aspect ratio features) in each DTC may be relaxed (i.e., reduced), thereby making processing and formation of the DTC easier. More specifically, the etching and subsequent filling of the trenches (or high aspect ratio features) may be easier at reduced depths, lengths, and/or aspect ratios.

Although the remaining disclosure will routinely identify specific processes utilizing the disclosed technology, it will be readily understood that the systems and methods are equally applicable to other processes as may occur in the described chambers. Accordingly, the technology should not be considered to be so limited as for use with the described processes or chambers alone. Moreover, although an exemplary chamber is described to provide foundation for the present technology, it is to be understood that the present technology can be applied to virtually any semiconductor processing chamber that may allow the single-chamber operations described.

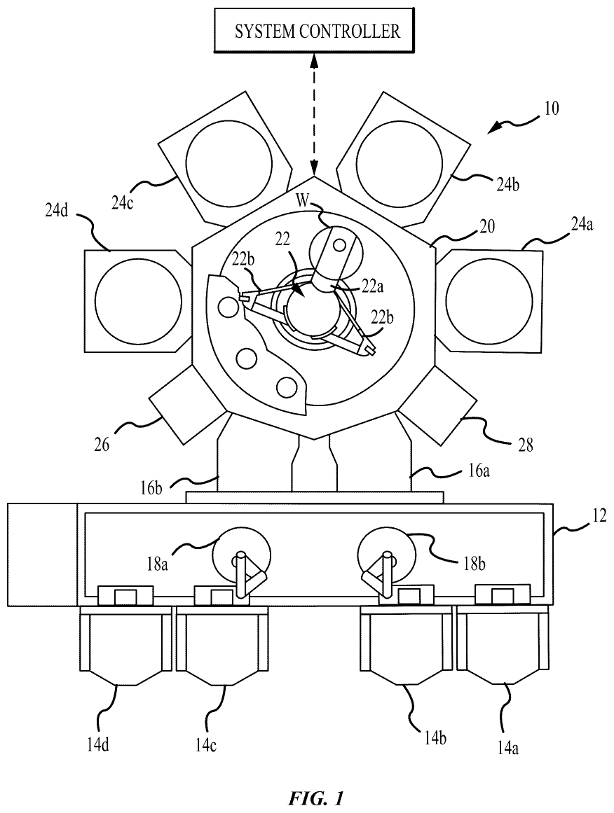

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

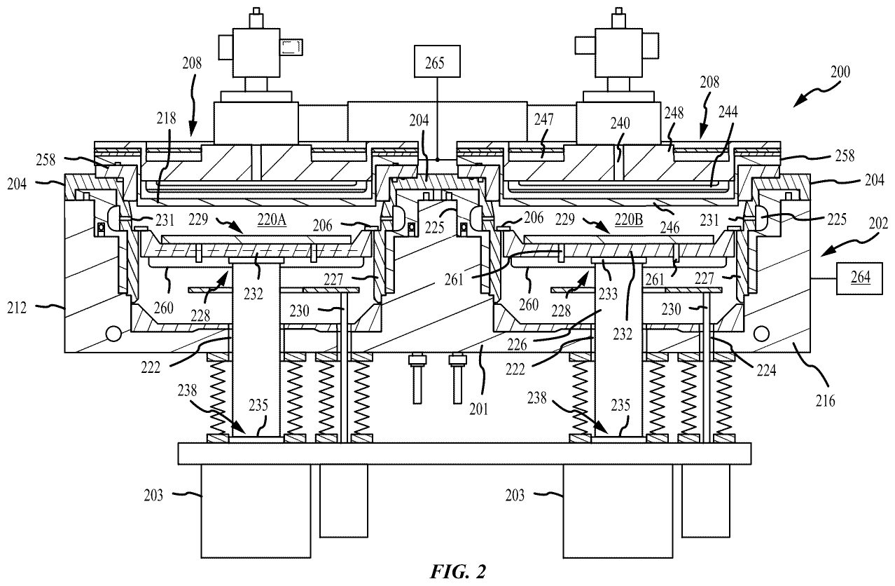

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include lid stack components according to embodiments of the present technology, and as may be explained further below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the precursor distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

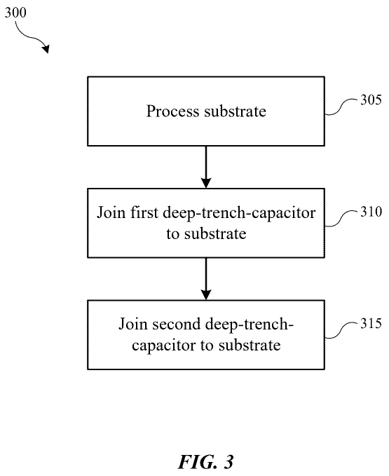

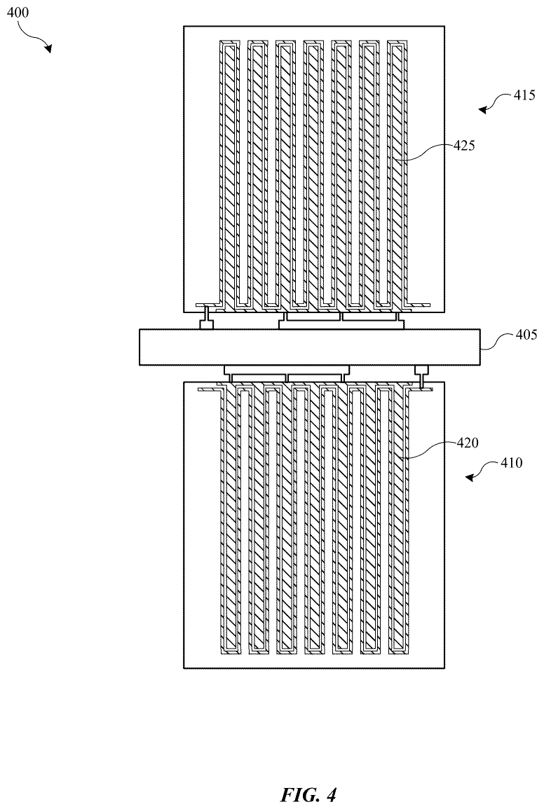

The chamber discussed previously may be used in performing exemplary methods, although any number of chambers may be configured to perform one or more aspects used in embodiments of the present technology. Turning to FIG. 3, exemplary operations in a method 300 according to embodiments of the present technology are shown. Method 300 may include one or more operations prior to the initiation of the method, including front end processing, deposition, etching, polishing, cleaning, back end of line (BEOL) processing, or any other operations that may be performed prior to the described operations. The methods may include a number of optional operations, which may or may not be specifically associated with some embodiments of methods, according to embodiments of the present technology. For example, many of the operations are described in order to provide a broader scope of the processes performed, but are not critical to the technology, or may be performed by alternative methodology as will be discussed further below. Method 300 may describe structures shown schematically in FIG. 4, the illustration of which will be described in conjunction with the operations of method 300. It is to be understood that the figures illustrate only partial schematic views, and a substrate may contain any number of additional materials and features having a variety of characteristics and aspects as illustrated in the figures.

Method 300 may or may not involve optional operations to develop the semiconductor structure to a particular fabrication operation. It is to be understood that method 300 may be performed on any number of semiconductor structures 400 or substrates 405, as illustrated in

FIG. 4, including exemplary structures on which deep-trench-capacitors (DTCs) may be joined or otherwise formed. As illustrated in FIG. 4, structure 400 may include a substrate 405. The substrate 405 may define a device layer. The device layer may include any structure, including memory and logic circuits, for example, that may require or benefit from added capacitance. However, it is also contemplated that the device layer may be any structure requiring or benefiting from DTCs that are part of a filtering circuit, part of a regulator circuit, and/or part of a decoupling circuit.

Method 300 may include processing the substrate 405 to form the device layer at operation 305. As previously discussed, the device layer may be any structure requiring or benefit from DTCs. For example, the device layer may be memory or logic structures, such as NAND, 3D NAND, DRAM, 3D DRAM structures, or any other structure.

At operation 310, method 300 may include joining the substrate 405 to a first DTC 410. The first DTC 410 may be coupled to a first surface of the substrate 405. At operation 315, method 300 may include joining the substrate 405 to a second DTC 415. The second DTC 415 may be coupled to a second surface of the substrate 405 to form a semiconductor structure. In embodiments, the second surface of the substrate 405 may be opposite the first surface of the substrate 405. While generally discussed as being joined to the substrate 405, the first DTC 410 and/or the second DTC 415 may be coupled or connected directly or indirectly. For example, some intervening layers, materials, or structures may be present between the first DTC 410 and/or the second DTC 415 and the substrate 405. Each of the first DTC 410 and the second DTC 415 may be joined or coupled to the substrate 405 using any conventional or yet-to-be developed methods as would be appreciated by one skilled in the art. Additionally, each of the first DTC 410 and the second DTC 415 may include any features or characteristics of conventional or yet to be developed DTCs as would be appreciated by one skilled in the art. Method 300 may optionally include processing operations to from each of the first DTC 410 and second DTC 415. Alternatively and for the sake of brevity, method 300 may include joining pre-fabricated DTCs to the substrate 405 at operations 310 and 315.

As will be appreciated by one skilled in the art, a DTC may be a three-dimensional vertical capacitor formed by etching a deep trench (DT) into a substrate, such as a silicon substrate. A doped region within the substrate adjacent to the trench forms one capacitor plate (i.e., a buried capacitor plate). A dielectric layer lining the trench forms the capacitor dielectric. Finally, a conductive fill material (e.g., a doped polysilicon) within the trench forms another capacitor plate. A standard contact can be formed to contact capacitor plate within the trench. However, the DTCs of the present technology may not be limited to this construction or configuration and may encompass any type of DTC. The DTC may be used to add capacitance to various integrated circuits.

The second DTC 415 may be coupled to a second surface of the substrate 405. The second surface of the substrate 405 may be opposite the first surface of the substrate 405. As such, the first DTC 410 and the second DTC 415 may extend from the substrate 405 in opposite directions. However, it is also contemplated that the first DTC 410 and the second DTC 415 may extend orthogonal from the substrate 405. Additionally, while the structure 400 is illustrated as including two DTCs extending in opposite directions from the substrate 405, it is contemplated that the structure 400 may include more than two DTCs. For example, the structure 400 could include three DTCs, four DTCs, five DTCs, six DTCs, or more.

The first DTC 410 may include a first plurality of high aspect ratio features 420. Similarly, the second DTC 415 may include a second plurality of high aspect ratio features 425. The first DTC 410 (and the first plurality of high aspect ratio features 420) and the second DTC 415 (and the second plurality of high aspect ratio features 425) may be the same or similar structures having the same or similar dimensions. However, it is also contemplated the first DTC 410 (and the first plurality of high aspect ratio features 420) and the second DTC 415 (and the second plurality of high aspect ratio features 425) may have different dimensions, which may depend on capacitance requirements, packaging dimensions, or other factors.

In embodiments, the first plurality of high aspect ratio features 420 and/or the second plurality of high aspect ratio features 425 may be characterized by an aspect ratio, or ratio of length to width, of less than or about 20:1. At higher aspect ratios, such as those common in conventional DTCs, capacitance may increase, but with unavoidable disadvantage of increasing ESL and/or ESR. With reduced aspect ratios of the first plurality of high aspect ratio features 420 and/or the second plurality of high aspect ratio features 425, the structure 400 may be characterized by reduced ESL and/or ESR. As such, the first plurality of high aspect ratio features 420 and/or the second plurality of high aspect ratio features 425 may be characterized by an aspect ratio of less than or about 18:1, less than or about 16:1, less than or about 15:1, less than or about 14:1, less than or about 13:1, less than or about 12:1, less than or about 11:1, less than or about 10:1, less than or about 9:1, less than or about 8:1, or less.

As previously discussed, conventional DTCs may increase aspect ratio, by increasing depth or length of the plurality of high aspect ratios in the DTC, to increase capacitance. However, increased depth or length of the plurality of high aspect ratios in the DTC increase a resultant inductance and/or resistance parasitic tradeoff. Conversely, the DTCs of the present technology may be characterized by a reduced depth or length compared to conventional DTCs. In embodiments, the first plurality of high aspect ratio features 420 and/or the second plurality of high aspect ratio features 425 may be characterized by a depth or length of less than or about 4 micron (μm), and may be characterized by a depth or length of less than or about 3.8 μm, less than or about 3.6 μm, less than or about 3.5 μm, less than or about 3.4 μm, less than or about 3.3 μm, less than or about 3.2 μm, less than or about 3.1 μm, less than or about 3 μm, less than or about 2.9 μm, less than or about 2.8 μm, less than or about 2.7 μm, less than or about 2.6 μm, less than or about 2.5 μm, or less. However, to maintain necessary or desired capacitance, the first plurality of high aspect ratio features 420 and/or the second plurality of high aspect ratio features 425 may be characterized by a depth or length of greater than or about 1 μm, greater than or about 1.2 μm, greater than or about 1.4 μm, greater than or about 1.6 μm, greater than or about 1.8 μm, greater than or about 2 μm, greater than or about 2.2 μm, greater than or about 2.4 μm, or more.

In embodiments, the first plurality of high aspect ratio features 420 and/or the second plurality of high aspect ratio features 425 may be characterized by a width of less than or about 500 nanometer (nm), and may be by a width of less than or about 475 nm, less than or about 450 nm, less than or about 425, nm, less than or about 400 nm, less than or about 375 nm, less than or about 350 nm, less than or about 325 nm, less than or about 300 nm, or less.

By incorporating multiple DTCs, such as the first DTC 410 and the second DTC 415, the structure 400 may be characterized by a capacitance density at about 1 gigahertz (GHz) of greater than or about 4×10⁻¹² farad (F). While conventional technologies may increase depth or length of the aspect ratios of the high aspect ratio features in the DTC, the present technology may increase the number of DTCs to increase capacitance. As such, the structure 400 may be characterized by a capacitance density at about 1 gigahertz (GHz) of greater than or about 4.5×10⁻¹² F, greater than or about 5×10⁻¹² F, greater than or about 5.5×10⁻¹² F, greater than or about 5.6×10⁻¹² F, greater than or about 5.7×10⁻¹² F, greater than or about 5.8×10⁻¹² F, greater than or about 5.9×10⁻¹² F, greater than or about 6.0×10⁻¹² F, greater than or about 6.1×10⁻¹² F, greater than or about 6.2×10⁻¹² F, greater than or about 6.3×10⁻¹² F, or more.

Additionally, by incorporating multiple DTCs, such as the first DTC 410 and the second DTC 415, the structure 400 may be characterized by an ESL at about 1 GHz of less than or about 7×10⁻⁹ henry (H). Conventional technologies may not be able to achieve necessary capacitance while also maintaining and/or reducing ESL. In embodiments, the structure 400 may be characterized by an ESL at about 1 GHz of less than or about 7×10⁻⁹ H, less than or about 6.5×10⁻⁹ H, less than or about 6×10⁻⁹ H, less than or about 5.5×10⁻⁹ H, less than or about 5×10⁻⁹ H, less than or about 4.9×10⁻⁹ H, less than or about 4.8×10⁻⁹ H, less than or about 4.7×10⁻⁹ H, less than or about 4.6×10⁻⁹ H, less than or about 4.5×10⁻⁹ H, less than or about 4.4×10⁻⁹ H, less than or about 4.3×10⁻⁹ H, less than or about 4.2×10⁻⁹ H, less than or about 4.1×10⁻⁹ H, less than or about 4.0×10⁻⁹ H, or less.

Similarly, by incorporating multiple DTCs, such as the first DTC 410 and the second DTC 415, the structure 400 may be characterized by an ESR at about 1 GHz of less than or about 5 ohm (Ω). Conventional technologies may not be able to achieve necessary capacitance while also maintaining and/or reducing ESR. In embodiments, the structure 400 may be characterized by an ESR at about 1 GHz of less than or about 4.5Ω, less than or about 4Ω, less than or about 3.5Ω, less than or about 3.4Ω, less than or about 3.3Ω, less than or about 3.2Ω, less than or about 3.1Ω, less than or about 3.0Ω, less than or about 2.9Ω, less than or about 2.8Ω, less than or about 2.7Ω, less than or about 2.6Ω, less than or about 2.5, or less.

As device layers may be moved to a middle portion of the chip stack, the present technology may desirably address issues associated with conventional structures and resultant electrical properties. More specifically, the incorporation of additional DTCs, such as a second DTC, in a structure, may increase capacitance density while maintaining and/or reducing ESR and/or ESL.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

As used herein and in the appended claims, the singular forms “a”, “an”, and “the” include plural references unless the context clearly dictates otherwise. Thus, for example, reference to “a device layer” includes a plurality of such layers, and reference to “the first DTC” includes reference to one or more tilted DTCs and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor structure comprising:
a substrate defining a device layer;
a first deep-trench-capacitor (DTC) coupled to a first surface of the substrate; and
a second DTC coupled to a second surface of the substrate opposite the first surface of the substrate.

2. The semiconductor structure of claim 1, wherein:
the first DTC comprises a first plurality of high aspect ratio features; and
the second DTC comprises a second plurality of high aspect ratio features.

3. The semiconductor structure of claim 2, wherein an aspect ratio of first plurality of high aspect ratio features is approximately the same as an aspect ratio of the second plurality of high aspect ratio features.

4. The semiconductor structure of claim 2, wherein the first plurality of high aspect ratio features, the second plurality of high aspect ratio features, or both are characterized by a depth of less than or about 4 micron (μm).

5. The semiconductor structure of claim 2, wherein the first plurality of high aspect ratio features, the second plurality of high aspect ratio features, or both are characterized by a depth of less than or about 3 micron (μm).

6. The semiconductor structure of claim 2, wherein the first plurality of high aspect ratio features, the second plurality of high aspect ratio features, or both are characterized by a width of less than or about 500 nanometer (nm).

7. The semiconductor structure of claim 2, wherein the first plurality of high aspect ratio features, the second plurality of high aspect ratio features, or both are characterized by an aspect ratio of less than or about 20:1.

8. The semiconductor structure of claim 1, wherein the semiconductor structure is characterized by a capacitance density at about 1 gigahertz (GHz) of greater than or about 4×10⁻¹² farad (F).

9. The semiconductor structure of claim 1, wherein the semiconductor structure is characterized by an equivalent series inductance (ESL) at about 1 gigahertz (GHz) of less than or about 7×10⁻⁹ henry (H).

10. The semiconductor structure of claim 1, wherein the semiconductor structure is characterized by an equivalent series resistance (ESR) at about 1 gigahertz (GHz) of less than or about 5 ohm (Ω).

11. A semiconductor processing method comprising:
processing a substrate to form a device layer;
joining the substrate to a first deep-trench-capacitor (DTC), wherein the first DTC is coupled to a first surface of the substrate; and
joining the substrate to a second DTC, wherein the second DTC is coupled to a second surface of the substrate to form a semiconductor structure.

12. The semiconductor processing method of claim 11, wherein:
the first DTC comprises a first plurality of high aspect ratio features; and
the second DTC comprises a second plurality of high aspect ratio features.

13. The semiconductor processing method of claim 12, wherein the first plurality of high aspect ratio features, the second plurality of high aspect ratio features, or both are characterized by an aspect ratio of less than or about 20:1.

14. The semiconductor processing method of claim 12, wherein the first plurality of high aspect ratio features, the second plurality of high aspect ratio features, or both are characterized by a depth of less than or about 4 micron (μm).

15. The semiconductor processing method of claim 11, wherein the semiconductor structure is characterized by a capacitance density at about 1 gigahertz (GHz) of greater than or about 4×10⁻¹² farad (F).

16. The semiconductor processing method of claim 11, wherein:
the semiconductor structure is characterized by an equivalent series inductance (ESL) at about 1 gigahertz (GHz) of less than or about 7×10⁻⁹ henry (H); or
the semiconductor structure is characterized by an equivalent series resistance (ESR) at about 1 gigahertz (GHz) of less than or about 5 ohm (Ω).

17. A semiconductor structure comprising:
a substrate defining a device layer;
first deep-trench-capacitor (DTC) comprising a first plurality of high aspect ratio features coupled to a first surface of the substrate; and
second DTC coupled comprising a second plurality of high aspect ratio features to a second surface of the substrate, wherein the semiconductor structure is characterized by:
a capacitance density at about 1 gigahertz (GHz) of greater than or about 4×10⁻¹² farad (F); and
an equivalent series inductance (ESL) at about 1 gigahertz (GHz) of less than or about 7×10⁻⁹ henry (H), an equivalent series resistance (ESR) at about 1 gigahertz (GHz) of less than or about 5 ohm (Ω), or both.

18. The semiconductor structure of claim 17, wherein the first plurality of high aspect ratio features, the second plurality of high aspect ratio features, or both are characterized by an aspect ratio of less than or about 20:1.

19. The semiconductor structure of claim 17, wherein the first plurality of high aspect ratio features, the second plurality of high aspect ratio features, or both are characterized by a depth of less than or about 4 micron (μm).

20. The semiconductor structure of claim 17, wherein the semiconductor structure is characterized by an equivalent series inductance (ESL) at about 1 gigahertz (GHz) of less than or about 7×10⁻⁹ henry (H) and an equivalent series resistance (ESR) at about 1 gigahertz (GHz) of less than or about 5 ohm (Ω).
